(19) United States
(12) Patent Application Publication
(10) Pub. No.: US 2024/0111267 A1
(43) Pub. Date: Apr. 4, 2024

(54) CONTROL SYSTEM FOR ELECTRIC LIFTING DESK AND ELECTRIC LIFTING DESK

(71) Applicant: DEWERTOKIN TECHNOLOGY GROUP CO., LTD., Jiaxing (CN)

(72) Inventors: Long LI, Jiaxing (CN); HUI LIU, Jiaxing (CN)

(21) Appl. No.: 18/276,286

(22) PCT Filed: Jan. 26, 2022
(86) PCT No.: PCT/CN2022/073948

§ 371 Date: Aug. 8, 2023

(30) Foreign Application Priority Data
Feb. 8, 2021 (CN) 202110172287.6

(51) Int. Cl. G05B 19/4155

(52) U.S. Cl. CPC G05B 19/4155; G05B 2219/45014

(57) ABSTRACT

Provided are a control system for an electric lifting desk and an electric lifting desk. The control system includes a controller and a motor driver circuit, and the controller includes a microprocessor, a measured voltage acquisition circuit and a measured voltage acquisition terminal. The motor driver circuit is configured to drive the lifting of at least one column, and the motor driver circuit includes a measured voltage generation circuit and a measured voltage output terminal. When the number of columns and/or the column type of the electric lifting desk is different, the value of a measured voltage output by the measured voltage generation circuit is different. The microprocessor is configured to determine whether the controller is connected to the motor driver circuit according to a voltage signal provided by the measured voltage acquisition circuit, and to determine the number of columns and/or the column type.

### CROSS-REFERENCE TO RELATED APPLICATIONS

This is a National Stage Application, filed under 35 U.S.C. 371, of International Patent Application No. PCT/CN2022/073948, filed on Jan. 26, 2022, which claims priority to Chinese Patent Application No. 202110172287.6 filed with the China National Intellectual Property Administration (CNIPA) on Feb. 8, 2021, the disclosures of which are incorporated herein by reference in their entireties.

### TECHNICAL FIELD

The present application relates to the technical field of electric lifting desks, for example, a control system for an electric lifting desk and an electric lifting desk.

### BACKGROUND

As social electronic technologies develop, various kinds of smart furniture have been increasingly chosen and used by users. Electric lifting desks are widely used as a type of smart furniture. With the increasing popularity of electric lifting desks, customization requirements of customers are also different. For an electrical lifting desk, some customers require a single column, some customers require two columns, some customers require three columns, etc. Requirements for the column type are also different, some customers require two-section columns, some customers require three-section columns, etc. For these different requirements, a common approach is to provide controllers with different serial numbers and corresponding to different software, resulting in a wide variety of controllers and increasing management and inventory costs.

### SUMMARY

The present application provides a control system for an electric lifting desk and an electric lifting desk, so that the connection manner between a controller and a to-be-controlled column is improved, the determination of the number of columns and the column type by the controller is achieved, and thus the management costs are reduced.

The present application provides a control system for an electric lifting desk, the electric lifting desk includes at least one column, and the control system includes a controller and a motor driver circuit.

The controller includes a microprocessor, a measured voltage acquisition circuit and a measured voltage acquisition terminal, an input of the measured voltage acquisition circuit and an output of the measured voltage acquisition circuit are connected to the measured voltage acquisition terminal and the microprocessor, respectively.

The motor driver circuit is configured to drive the lifting of at least one column, where the motor driver circuit includes a measured voltage generation circuit and a measured voltage output terminal, and an output of the measured voltage generation circuit is electrically connected to the measured voltage output terminal; and the measured voltage generation circuit is configured to output a different value of a measured voltage in a case of a different number of columns of the electric lifting desk and/or a different column type of the electric lifting desk.

The measured voltage acquisition terminal is electrically connected to the measured voltage output terminal; and the microprocessor is configured to determine whether the controller is connected to the motor driver circuit according to a voltage signal provided by the measured voltage acquisition circuit and determine the number of columns and/or the column type.

The present application further provides an electric lifting desk including the preceding control system and at least one column.

### BRIEF DESCRIPTION OF DRAWINGS

FIG. 1 is a structural diagram of a control system for an electric lifting desk according to an embodiment of the present application;

FIG. 2 is a circuit connection diagram of a control system for an electric lifting desk according to an embodiment of the present application;

FIG. 3 is an equivalent circuit diagram of a control system for an electric lifting desk according to an embodiment of the present application; and

FIG. 4 is a structural diagram of an electric lifting desk according to an embodiment of the present application.

### DETAILED DESCRIPTION

The technical scheme of the present application is described hereinafter through implementations in conjunction with the drawings in embodiments of the present application. The described embodiments are part of embodiments of the present application.

FIG. 1 is a structural diagram of a control system for an electric lifting desk according to an embodiment of the present application. As shown in FIG. 1, the control system 100 includes a controller 101 and a motor driver circuit 102. The controller 101 includes a microprocessor 103, a measured voltage acquisition circuit 104 and a measured voltage acquisition terminal 105. The input and the output of the measured voltage acquisition 104 are connected to the measured voltage acquisition terminal 105 and the microprocessor 103, respectively. The motor driver circuit 102 is configured to drive the lifting of at least one column. The motor driver circuit includes a measured voltage generation circuit 106 and a measured voltage output terminal 107, and the output of the measured voltage generation circuit 106 is electrically connected to the measured voltage output terminal 107. When the number of columns and/or the column type of the electric lifting desk is different, the value of the measured voltage output by the measured voltage generation circuit 106 is different. The measured voltage acquisition terminal 105 is electrically connected to the measured voltage output terminal 107; the microprocessor 103 is configured to determine whether the controller 101 is connected to the motor driver circuit 102 according to the voltage signal provided by the measured voltage acquisition circuit 104, and the microprocessor 103 is also configured to determine the number of columns and/or the column type of the electric lifting desk.

The microprocessor 103 may be a single-chip computer inside the controller 101 and is configured to perform analysis and processing on the voltage signal provided by the measured voltage acquisition circuit 104, determine a connection relationship between the motor driver circuit 102 and the controller 101, and then determine the number and/or the type of columns driven by the motor driver circuit 102 through different measured voltages provided by the motor driver circuit and corresponding to different numbers of columns and/or different column types. A port where the microprocessor 103 is electrically connected to the measured voltage acquisition circuit 104 is a digital-to-analog conversion port. The digital-to-analog conversion port is configured to convert a received voltage signal into a digital signal so that the microprocessor 103 performs the analysis, processing and determination on the digital signal to determine the measured voltage provided by the measured voltage generation circuit 106 of the motor driver circuit 102, and thus the number of columns and/or the column type corresponding to the connected motor driver circuit 102 can be determined according to different measured voltages. Multiple measured voltage acquisition terminals 105 and multiple measured voltage output terminals 107 may both be provided. Multiple measured voltage acquisition terminals 105 and multiple measured voltage output terminals 107 are electrically connected in one-to-one correspondence. The measured voltage acquisition terminal 105 and the measured voltage output terminal 107 may be set according to actual requirements.

The control system 100 provided in the embodiment of the present application includes a controller 101 and at least one motor driver circuit 102. At least one hole is provided on the controller 101, a column is mounted in each hole, and each motor driver circuit 102 is disposed in the column. That is, the number of motor driver circuits 102 is the same as the number of holes in the control system 100, the at least one motor driver circuit 102 and the at least one hole are in one-to-one correspondence. Each motor driver circuit 102 is configured to drive a column, when this column where the motor driver circuit 102 is located is mounted in the hole. When a column is mounted in a hole of the controller 101, the controller 101 forms a circuit with the motor driver circuit 102 of this column so that a corresponding equivalent resistance value exists in the motor drive circuit 102 of the column. Therefore, whether a column is mounted in a hole of the controller 101 may be determined according to the equivalent resistance value of the motor driver circuit 102.

The number of measured voltage acquisition circuits 104 and the number of measured voltage acquisition terminals 105 in the controller 101 are both the same as the number of holes provided on the controller 101, at least one measured voltage acquisition circuit 104 is connected to at least one measured voltage acquisition terminal 105 in one-to-one correspondence, and the at least one measured voltage acquisition terminal 105 and at least one hole are in one-to-one correspondence. Each measured voltage acquisition terminal 105 is configured to be connected to a motor driver circuit 102 of a column, when the column is mounted in the hole corresponding to the measured voltage acquisition terminal 105. The microprocessor 103 is configured to determine whether a measured voltage acquisition terminal 105 connected to each measured voltage acquisition circuit 104 is connected to the motor driver circuit 102 according to the voltage signal provided by each measured voltage acquisition circuit 104, and then determine whether a column is mounted in the hole corresponding to the measured voltage acquisition terminal 105. When it is determined that a column is mounted in the hole corresponding to the measured voltage acquisition terminal 105, the microprocessor 103 may also determine the column type according to the equivalent resistance value.

FIG. 1 is only a structural diagram showing the connection between a motor driver circuit 102 and a group of the measured voltage acquisition circuit 104 and the measured voltage acquisition terminal 105 in the controller 101. The structural diagram shown in FIG. 1 is used for determining whether a column is mounted in a hole on the control system 100, and also used for determining the column type if the column is mounted in the hole.

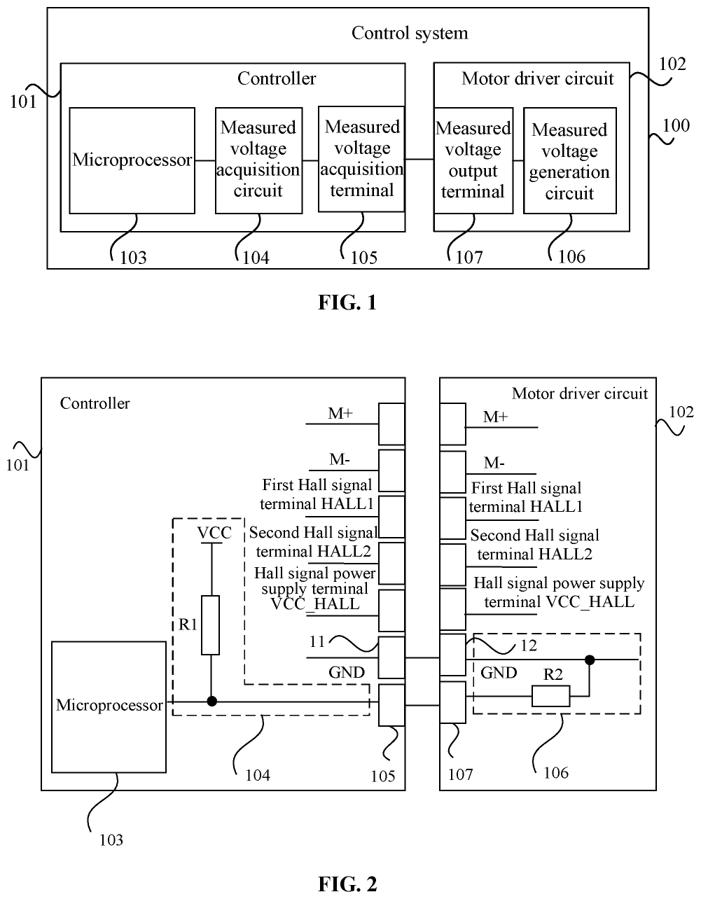

FIG. 2 is a circuit connection diagram of a control system for an electric lifting desk according to an embodiment of the present application. As shown in FIG. 2, in an embodiment, the measured voltage acquisition circuit 104 may include a first resistor R1, a first end of the first resistor R1 is electrically connected to a power supply voltage terminal VCC, and a second end of the first resistor R1 is electrically connected to both the measured voltage acquisition terminal 105 and the microprocessor 103.

In an embodiment, the controller 101 may also include a first ground terminal 11, the motor driver circuit 102 also includes a second ground terminal 12, and the second ground terminal 12 is connected to the first ground terminal 11. The measured voltage generation circuit 106 includes a second resistor R2, a first end of the second resistor R2 is electrically connected to the second ground terminal, and a second end of the second resistor R2 is electrically connected to the measured voltage output terminal 107.

The resistance value of the second resistor R2 corresponds to both the number of columns and the column type.

In an embodiment, the resistance value of the first resistor R1 is the same as or different from the resistance value of the second resistor R2.

With continued reference to FIG. 2, the resistance value of the first resistor R1 is fixed. For example, the resistance value of the first resistor R1 may be 10K, 20K, etc. In the measurement process, the resistance value of the first resistor R1 is set to a fixed value, which can facilitate the microprocessor 103 executing its function and ensure the accuracy of the measurement result. The first end of the second resistor R2 is electrically connected to the second ground terminal 12, and the second end of the second resistor R2 is electrically connected to the measured voltage output terminal 107. The controller 101 also includes the first ground terminal 11. The first ground terminal 11 is electrically connected to the second ground terminal 12, and both the first ground terminal 11 and the second ground terminal 12 are connected to a ground terminal GND. The second resistor R2 may be set according to different column types, and resistance values of the second resistor R2 corresponding to different column types are different, ensuring the accuracy of the determination result of the microprocessor 103. The resistance value of the first resistor R1 may be the same as or different from the resistance value of the second resistor R2, and the accuracy of the measurement result can be ensured in both two cases.

In an embodiment, the microprocessor 103 is configured to compare the voltage signal provided by the measured voltage acquisition circuit 104 with a power supply voltage signal, and when the voltage signal provided by the measured voltage acquisition circuit 104 is equal to the power supply voltage signal, the microprocessor 103 is configured to determine that the controller 101 is disconnected from the motor driver circuit 102, and when the voltage signal provided by the measured voltage acquisition circuit 104 is less than the power supply voltage signal, the microprocessor 103 is configured to determine that the controller 101 is connected to the motor driver circuit 102.

Similar to FIG. 1, FIG. 2 only shows a diagram of the circuit connection between a motor driver circuit 102 and a group of the measured voltage acquisition circuit 104 and the measured voltage acquisition terminal 105 in the controller 101. The resistance value of the second resistor R2 is the equivalent resistance value in the motor driver circuit 102. The resistance value of the second resistor R2 corresponding to both the number of columns and the column type refers to that whether a column where the motor driver circuit 102 is located is mounted in a hole may be determined according to the resistance value of the second resistor R2, and that the column type may be determined according to the resistance value of the second resistor R2 when the column where the motor driver circuit 102 is located is mounted in the hole. In the embodiment, the resistance value of the second resistor R2 varies due to whether the column is mounted and the mounted-column type.

The controller 101 being disconnected from the motor driver circuit 102 actually refers to that no column is mounted in the corresponding hole of the controller 101, which is equivalent to an infinite resistance value corresponding to the second resistor R2. The controller 101 being connected to the motor driver circuit 102 actually refers to that a column is mounted in the corresponding hole of the controller 101, that is, in FIG. 2, the resistance value corresponding to the second resistor R2 corresponds to the column type.

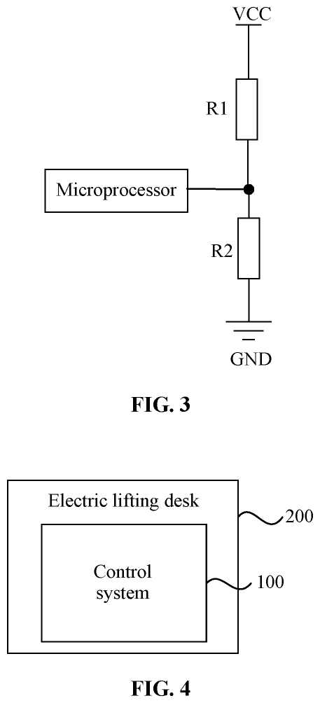

FIG. 3 is an equivalent circuit diagram of a control system for an electric lifting desk according to an embodiment of the present application. The measured voltage generation circuit 106 is determined by the second resistor R2. Since the measured voltage acquisition terminal 105 is electrically connected to the measured voltage output terminal 107, the measured voltage output terminal 107 outputs a voltage signal corresponding to the second resistor R2, the measured voltage acquisition terminal 105 receives the voltage signal corresponding to the second resistor R2 and output by the measured voltage output terminal 107, and the microprocessor 103 receives the voltage signal corresponding to the second resistor R2 and a voltage signal corresponding to the first resistor R1. As shown in FIG. 3, the first resistor R1 is connected in parallel with the second resistor R2. When the controller 101 is disconnected from the motor driver circuit 102, the voltage signal corresponding to the second resistor R2 is infinite. At this time, the voltage signal received by the microprocessor 103 is equal to the power supply voltage, that is, the measured voltage output terminal 107 of the motor driver circuit 102 is not connected to the column. When the controller 101 is connected to the motor driver circuit 102, the first resistor R1 and the second resistor R2 connected in parallel have the voltage division function. At this time, the voltage signal received by the microprocessor 103 is less than the power supply voltage, that is, the measured voltage output terminal 107 of the motor driver circuit 102 is connected to a column.

In an embodiment, the number of columns is greater than or equal to zero; and the column type includes at least one of a two-section column or a three-section column.

The number of columns of the control system 100 may be set according to actual requirements. The number of columns may include one, two, three, four, etc. The number of columns connected to the measured voltage output terminal 107 of the motor driver circuit 102 may be determined as zero. The column type may include a two-section column and a three-section column. For example, it may be set that the resistance value of the second resistor R2 corresponding to the two-section column is 10K, and the resistance value of the second resistor R2 corresponding to the three-section column is 20K. The corresponding number of columns may be determined in combination with the column type according to requirements.

In an embodiment, the power supply voltage VCC may be 3.3 V, 5 V or 12 V.

The voltage value of the power supply voltage VCC is generally the same as the power supply voltage of the microprocessor 103 in the controller 101, reducing the set external power supply type and the cost.

The microprocessor 103 is also configured to, when the voltage signal provided by the measured voltage acquisition circuit 104 is less than the power supply voltage signal, determine the resistance value of the second resistor R2 according to a voltage signal calculation formula that V=VCC*R2/(R1+R2) and a known resistance value of the first resistor R1, and then determine the number of columns and/or the column type of the electric lifting desk according to a correspondence between the resistance value of the second resistor R2 and the number of columns and/or the column type.

With continued reference to FIG. 2 and FIG. 3, different column types correspond to different resistance values of the second resistance R2, therefore, the microprocessor 103 may perform analysis according to different received voltage signals and determine the column type in combination with voltage signal values that correspond to different column types and are preset in the microprocessor 103. When the resistance value of the first resistor R1 is 10K, the resistance value of the second resistor R2 corresponding to the two-section column is 10K, the resistance value of the second resistor R2 corresponding to the three-section column is 20K, and the power supply voltage VCC is 5 V. When the resistance value of the second resistor R2 preset in the microprocessor 103 is 10K, the corresponding voltage signal value provided by the measured voltage acquisition circuit 104 is 2.5 V; and when the resistance value of the second resistor R2 is 20K, the corresponding voltage signal value provided by the measured voltage acquisition circuit 104 is 3.33 V. When the voltage signal V received by the microprocessor 103 and provided by the measured voltage acquisition circuit 104 satisfies that V=5*20/(10+20)=3.33 V, it may be determined that the measured voltage output terminal 107 of the motor driver circuit 102 is electrically connected to a column, and the column type is a three-section column.

In an embodiment, the controller 101 may also include a forward rotation voltage terminal M+, a reverse rotation voltage terminal M−, a Hall signal terminal HALL and a Hall signal power supply terminal VCC_HALL. The forward rotation voltage terminal M+ is configured to transmit a forward rotation signal for controlling a motor electrically connected to the motor driver circuit 102; the reverse rotation voltage terminal M− is configured to transmit a reverse rotation signal for controlling the motor electrically connected to the motor driver circuit 102; the Hall signal terminal HALL is configured to transmit a rotor position signal of the motor; and the Hall signal power supply terminal VCC_HALL is configured to connect to an external device for supplying power to a Hall sensor inside the motor.

With continued reference to FIG. 2, to correspond to the controller 101, a forward rotation voltage terminal M+, a reverse rotation voltage terminal M−, a first Hall signal terminal HALL1, a second Hall signal terminal HALL2 and a Hall signal power supply terminal VCC_HALL are also disposed in the motor driver circuit 102, and ports of the same type in the controller 101 and the motor driver circuit 102 are in one-to-one correspondence. In this manner, the correct and orderly transmission of multiple signals is ensured, which facilitates the controller 101 outputting a control signal for controlling the operation of the motor driver circuit 102 and thus adjusting the lifting of the column.

The present application provides a control system for an electric lifting desk and an electric lifting desk. The electric lifting desk includes at least one column, the control system includes a controller and a motor driver circuit, and the control includes a microprocessor, a measured voltage acquisition circuit and a measured voltage acquisition terminal. The motor driver circuit is configured to drive the lifting of at least one column, and the motor driver circuit includes a measured voltage generation circuit and a measured voltage output terminal. Through the signal transmission among the microprocessor, the measured voltage acquisition circuit, the measured voltage acquisition terminal, the measured voltage generation circuit and the measured voltage output terminal, whether the controller is connected to the motor driver circuit is determined, and the number of columns and/or the column type is determined. The connection relationship between the controller and the column is improved, the accurate determination of the number of columns and/or the column type by the controller is achieved, and thus the management cost is reduced.

Based on the same concept, the present application also provides an electric lifting desk. FIG. 4 is a structural diagram of an electric lifting desk according to an embodiment of the present application. The electric lifting desk 200 includes the control system 100 in any one of the preceding embodiments and at least one column.

The electric lifting desk provided in the embodiment has the same or corresponding effects as any one of the preceding control systems, which will not be repeated here.

1. A control system for an electric lifting desk, wherein the electric lifting desk comprises at least one column, and the control system comprises:
a controller, wherein the controller comprises a microprocessor, a measured voltage acquisition circuit and a measured voltage acquisition terminal, wherein an input of the measured voltage acquisition circuit and an output of the measured voltage acquisition circuit are connected to the measured voltage acquisition terminal and the microprocessor, respectively; and
a motor driver circuit configured to drive lifting of the at least one column, wherein the motor driver circuit comprises a measured voltage generation circuit and a measured voltage output terminal, and an output of the measured voltage generation circuit is electrically connected to the measured voltage output terminal; wherein the measured voltage generation circuit is configured to output a different value of a measured voltage in a case of at least one of a different number of columns of the electric lifting desk or a different column type of the electric lifting desk;
wherein the measured voltage acquisition terminal is electrically connected to the measured voltage output terminal; and the microprocessor is configured to determine, according to a voltage signal provided by the measured voltage acquisition circuit, whether the controller is connected to the motor driver circuit and determine at least one of the number of columns of the electric lifting desk or the column type of the electric lifting desk.

2. The control system according to claim 1, wherein the measured voltage acquisition circuit comprises a first resistor R1, a first end of the first resistor R1 is configured to be electrically connected to a power supply voltage terminal VCC, and a second end of the first resistor R1 is electrically connected to both the measured voltage acquisition terminal and the microprocessor.

3. The control system according to claim 2, wherein the controller further comprises a first ground terminal, the motor driver circuit further comprises a second ground terminal, and the second ground terminal is connected to the first ground terminal;
the measured voltage generation circuit comprises a second resistor R2, a first end of the second resistor R2 is electrically connected to the second ground terminal, and a second end of the second resistor R2 is electrically connected to the measured voltage output terminal; and
a resistance value of the second resistor R2 corresponds to both the number of columns of the electric lifting desk and the column type of the electric lifting desk.

4. The control system according to claim 3, wherein the microprocessor is configured to determine, according to the voltage signal provided by the measured voltage acquisition circuit, whether the controller is connected to the motor driver circuit in the following manner:
comparing the voltage signal provided by the measured voltage acquisition circuit with a power supply voltage signal, in a case where the voltage signal provided by the measured voltage acquisition circuit is equal to the power supply voltage signal, determining that the controller is disconnected from the motor driver circuit; and in a case where the voltage signal provided by the measured voltage acquisition circuit is less than the power supply voltage signal, determining that the controller is connected to the motor driver circuit.

5. The control system according to claim 4, wherein the microprocessor is configured to determine the at least one of the number of columns of the electric lifting desk or the column type of the electric lifting desk in the following manner:
in the case where the voltage signal provided by the measured voltage acquisition circuit is less than the power supply voltage signal, determining the resistance value of the second resistor R2 according to a known resistance value of the first resistor R1 and a voltage signal calculation formula that V=VCC*R2/(R1+R2), and determining, according to a correspondence between the resistance value of the second resistor R2 and the at least one of the number of columns of the electric lifting desk or the column type of the electric lifting desk, the at least one of the number of columns of the electric lifting desk or the column type of the electric lifting desk.

6. The control system according to claim 3, wherein a resistance value of the first resistor R1 is the same as or different from the resistance value of the second resistor R2.

7. The control system according to claim 2, wherein the power supply voltage VCC is 3.3 V, 5V or 12 V.

8. The control system according to claim 1, wherein the number of columns is larger than or equal to zero; and the column type comprises at least one of a two-section column and a three-section column.

9. The control system according to claim 1, wherein the controller further comprises a forward rotation voltage terminal M+, a reverse rotation voltage terminal M−, a Hall signal terminal HALL and a Hall signal power supply terminal VCC_HALL; and
the forward rotation voltage terminal M+ is configured to transmit a forward rotation signal for controlling a motor electrically connected to the motor driver circuit; the reverse rotation voltage terminal M− is configured to transmit a reverse rotation signal for controlling the motor electrically connected to the motor driver circuit; the Hall signal terminal is configured to transmit a rotor position signal of the motor; and the Hall signal power supply terminal VCC_HALL is configured to connect to an external device for supplying power to a Hall sensor inside the motor.

10. An electric lifting desk, comprising a control system and at least one column;
the control system comprises a controller and a motor driver circuit;
wherein the controller comprises a microprocessor, a measured voltage acquisition circuit and a measured voltage acquisition terminal, wherein an input of the measured voltage acquisition circuit and an output of the measured voltage acquisition circuit are connected to the measured voltage acquisition terminal and the microprocessor, respectively;
the motor driver circuit is configured to drive lifting of the at least one column, the motor driver circuit comprises a measured voltage generation circuit and a measured voltage output terminal, and an output of the measured voltage generation circuit is electrically connected to the measured voltage output terminal; wherein the measured voltage generation circuit is configured to output a different value of a measured voltage in a case of at least one of a different number of columns of the electric lifting desk or a different column type of the electric lifting desk;
wherein the measured voltage acquisition terminal is electrically connected to the measured voltage output terminal; and the microprocessor is configured to determine, according to a voltage signal provided by the measured voltage acquisition circuit, whether the controller is connected to the motor driver circuit and determine at least one of the number of columns of the electric lifting desk or the column type of the electric lifting desk.

11. The electric lifting desk according to claim 10, wherein the measured voltage acquisition circuit comprises a first resistor R1, a first end of the first resistor R1 is configured to be electrically connected to a power supply voltage terminal VCC, and a second end of the first resistor R1 is electrically connected to both the measured voltage acquisition terminal and the microprocessor.

12. The electric lifting desk according to claim 11, wherein the controller further comprises a first ground terminal, the motor driver circuit further comprises a second ground terminal, and the second ground terminal is connected to the first ground terminal;
the measured voltage generation circuit comprises a second resistor R2, a first end of the second resistor R2 is electrically connected to the second ground terminal, and a second end of the second resistor R2 is electrically connected to the measured voltage output terminal; and
a resistance value of the second resistor R2 corresponds to both the number of columns of the electric lifting desk and the column type of the electric lifting desk.

13. The electric lifting desk according to claim 12, wherein the microprocessor is configured to determine, according to the voltage signal provided by the measured voltage acquisition circuit, whether the controller is connected to the motor driver circuit in the following manner:
comparing the voltage signal provided by the measured voltage acquisition circuit with a power supply voltage signal, in a case where the voltage signal provided by the measured voltage acquisition circuit is equal to the power supply voltage signal, determining that the controller is disconnected from the motor driver circuit; and in a case where the voltage signal provided by the measured voltage acquisition circuit is less than the power supply voltage signal, determining that the controller is connected to the motor driver circuit.

14. The electric lifting desk according to claim 13, wherein the microprocessor is configured to determine the at least one of the number of columns of the electric lifting desk or the column type of the electric lifting desk in the following manner:
in the case where the voltage signal provided by the measured voltage acquisition circuit is less than the power supply voltage signal, determining the resistance value of the second resistor R2 according to a known resistance value of the first resistor R1 and a voltage signal calculation formula that V=VCC*R2/(R1+R2), and determining, according to a correspondence between the resistance value of the second resistor R2 and the at least one of the number of columns of the electric lifting desk or the column type of the electric lifting desk, the at least one of the number of columns of the electric lifting desk or the column type of the electric lifting desk.

15. The electric lifting desk according to claim 12, wherein a resistance value of the first resistor R1 is the same as or different from the resistance value of the second resistor R2.

16. The electric lifting desk according to claim 11, wherein the power supply voltage VCC is 3.3 V, 5 V or 12 V.

17. The electric lifting desk according to claim 10, wherein the number of columns is larger than or equal to zero; and the column type comprises a two-section column and a three-section column.

18. The electric lifting desk according to claim 10, wherein the controller further comprises a forward rotation voltage terminal M+, a reverse rotation voltage terminal M−, a Hall signal terminal HALL and a Hall signal power supply terminal VCC_HALL; and
the forward rotation voltage terminal M+ is configured to transmit a forward rotation signal for controlling a motor electrically connected to the motor driver circuit; the reverse rotation voltage terminal M− is configured to transmit a reverse rotation signal for controlling the motor electrically connected to the motor driver circuit; the Hall signal terminal is configured to transmit a rotor position signal of the motor; and the Hall signal power supply terminal VCC_HALL is configured to connect to an external device for supplying power to a Hall sensor inside the motor.
